(19) United States
(12) Patent Application Publication
(10) Pub. No.: US 2026/0231458 A1
(43) Pub. Date: Aug. 6, 2026

(54) Wave Layout for High Electron Mobility Transistors

(71) Applicant: Alpha and Omega Semiconductor International LP, Toronto (CA)

(72) Inventors: Rahul Potera, Apex, NC (US); David Sheridan, Greensboro, NC (US)

(21) Appl. No.: 19/044,868

(22) Filed: Feb. 4, 2025

(51) Int. Cl. H10D 30/47; H10D 62/824

(52) U.S. Cl. CPC H10D 30/4732; H10D 62/824

(57) ABSTRACT

A semiconductor device is disclosed. The device includes a semiconductor substrate, a semiconductor spacer layer, and a semiconductor barrier layer. The spacer layer is located between the substrate and barrier layer. The spacer layer and barrier layer support formation of a two-dimensional electron gas (2DEG) proximate a heterojunction between the spacer and barrier layers. A high electron mobility transistor (HEMT) structure is formed on the barrier layer. Each cell of the HEMT structure has source contacts between first and second gate structures. The source contacts are island structures rather than continuous stripes. Island structures in adjacent cells are staggered with respect to each other along a width direction. The gate structures divert around the island structures to keep substantially constant spacing from source contacts and to keep substantially constant spacing between corresponding gate structures in cells adjacent to each other along the length direction.

### FIELD OF THE DISCLOSURE

Aspects of the present disclosure relate to semiconductor devices. More specifically, aspects of the present disclosure relate to a layout for high electron mobility transistors (HEMTs).

### BACKGROUND OF THE DISCLOSURE

A high-electron-mobility transistor (HEMT or HEM FET), also known as heterostructure FET (HFET) or modulation-doped FET (MODFET), is a field-effect transistor incorporating a junction between two materials with different band gaps (i.e., a heterojunction) as the channel instead of a doped region (as is generally the case for a MOSFET). The operation of an HEMT relies on the formation of a two-dimensional electron gas (2DEG) located heterojunction so that electric current can flow between a drain and source element via the 2DEG. Some examples of previously explored heterostructures for HEMTs include Aluminum-Gallium-Nitride/Gallium Nitride (AlGaN/GaN), Aluminum-Gallium-Arsenide/Gallium-Arsenide (AlGaAs/GaAs), Indium-Gallium-Arsenide/Gallium-Arsenide (InGaAs/GaAs), and Silicon/Silicon-Germanium (Si/SiGe).

Like other field effect transistors (FETs), HEMTs can be used as digital on-off switches in integrated circuits. HEMTs can operate at higher frequencies than ordinary transistors, up to millimeter wave frequencies, and are used in high-frequency products such as cell phones, satellite television receivers, voltage converters, radar equipment, satellite receivers, and low power amplifiers.

Gallium nitride based HEMTs are used as power switching transistors for voltage converter applications due to their low on-state resistances, low switching losses, and high breakdown strength. These gallium nitride enhanced voltage converter applications include AC adapters, which benefit from smaller package sizes due to the power circuitry requiring smaller passive electronic components.

Advantages of GaN-based HEMTs over other transistor architectures, such as Si-based MOSFETs, include higher operating temperatures, higher breakdown strengths, and lower specific on-state resistances, all in the case of GaN-based HEMTs compared to Si-based MOSFETs. Furthermore, Indium Phosphide based (InP-based) HEMTs exhibit low noise performance and higher switching speeds.

It is within this context that aspects of the present disclosure arise.

### BRIEF DESCRIPTION OF THE DRAWINGS

The teachings of the present disclosure can be readily understood by considering the following detailed description in conjunction with the accompanying drawings, in which:

FIG. 1A is a top-down schematic diagram of a layout of a prior art HEMT.

FIG. 1B is a cross-sectional schematic diagram of the prior art HEMT shown in FIG. 1A.

FIG. 2A is a top-down schematic diagram of a layout of an HEMT device according to aspects of the present disclosure.

FIG. 2B is a cross-sectional schematic diagram of the HEMT shown in FIG. 2A taken along line B-B of FIG. 2A.

FIG. 2C is a top-down schematic diagram of a layout of a portion of an HEMT device according to aspects of the present disclosure illustrating how the layout results in an increase in channel density.

FIG. 3A is a top-down schematic diagram of a layout of a prior art bi-directional HEMT.

FIG. 3B is a cross-sectional schematic diagram of the prior art bi-directional HEMT shown in FIG. 3A.

FIG. 4A is a top-down schematic diagram of a layout of a bi-directional HEMT device according to aspects of the present disclosure.

FIG. 4B is a cross-sectional schematic diagram of the bi-directional HEMT shown in FIG. 4A taken along line B-B of FIG. 4A.

FIG. 4C is a top-down schematic diagram of a layout of a portion of a bi-directional HEMT device according to aspects of the present disclosure illustrating how the layout results in an increase in channel density.

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the present disclosure. Accordingly, example embodiments of the present disclosure described below are set forth without any loss of generality to, and without imposing limitations upon, the claimed invention.

In the following Detailed Description, reference is made to the accompanying drawings, which form a part hereof, and in which are shown by way of illustration specific embodiments in which the invention may be practiced. In this regard, directional terminology, such as “top,” “bottom,” “front,” “back,” “leading,” “trailing,” etc., is used with reference to the orientation of the figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The disclosure herein refers to a semiconductor material, such as silicon, doped with ions of a first conductivity type or a second conductivity type. The ions of the first conductivity type may be opposite ions of the second conductivity type. For example, and without limitation, in some implementations, ions of the first conductivity type may be n-type, which contribute negative charge carriers, e.g., electrons, when doped into silicon. In such implementations, ions of the first conductivity type may include phosphorus, antimony, bismuth, lithium, and arsenic. In such implementations, ions of the second conductivity may be p-type, which create holes for charge carriers when doped into silicon and in this way are referred to as being the opposite of n-type. P-type type ions include boron, aluminum, gallium, and indium. While the above description referred to n-type as the first conductivity type and p-type as the second conductivity type the disclosure is not so limited, p-type may be the first conductivity type and n-type may be the second conductivity type. Furthermore, semiconductor materials other than silicon may be used in MOSFET devices in accordance with aspects of the present disclosure.

In the following Detailed Description, reference is made to the accompanying drawings, which form a part hereof, and which are shown by way of illustration of specific embodiments in which the invention may be practiced. For convenience, use of + or − after a designation of conductivity or net impurity carrier type (p or n) refers generally to a relative degree of concentration of a designated type of net impurity carriers within a semiconductor material. In general, terms, an n+ material has a higher n type net dopant (e.g., electron) concentration than an n material, and an n material has a higher carrier concentration than an n-material. Similarly, a p+ material has a higher p type net dopant (e.g., hole) concentration than a p material, and a p material has a higher concentration than a p-material. It is noted that what is relevant is the net concentration of the carriers, not necessarily dopant concentration. For example, a material may be heavily doped with n-type dopants but still have a relatively low net carrier concentration if the material is also sufficiently counter-doped with p-type dopants. As used herein, a concentration of dopants less than about 10¹⁵/cm³ may be regarded as “lightly doped” and a concentration of dopants greater than about 10¹⁷/cm³ may be regarded as “heavily doped”.

### INTRODUCTION

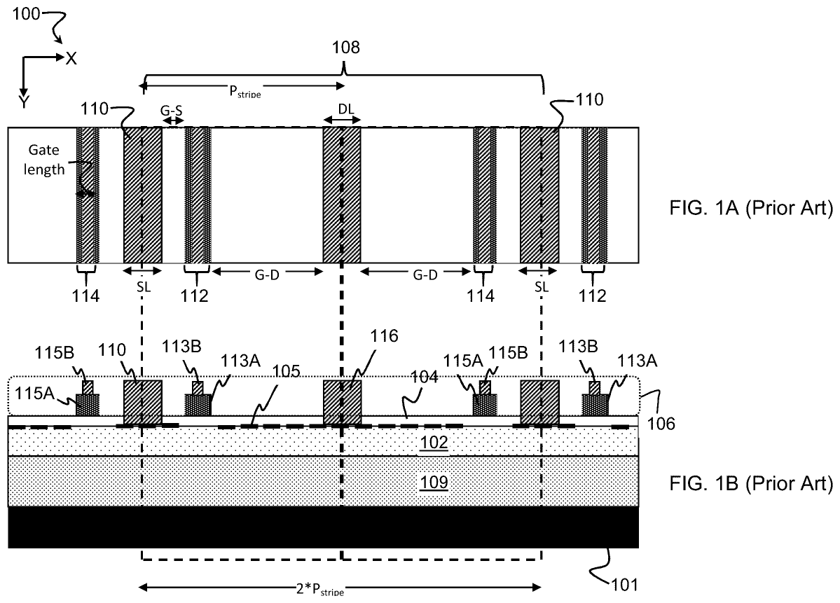

FIG. 1A and FIG. 1B illustrate a prior art uni-directional high electron mobility transistor (HEMT) device 100. As seen in FIG. 1B, this type of device generally includes a semiconductor substrate 101 made of a first semiconductor material, a spacer layer 102 made of a second material, and a barrier layer 104 made of a third semiconductor material. The spacer layer is located between the substrate and barrier layer. The barrier layer is located between the spacer layer and a high electron mobility transistor (HEMT) structure 106, made up of a plurality of cells 108 that extend along a length direction X. In some implementations, an optional buffer layer 109 made of a fourth semiconductor material may be located between the substrate and the spacer layer. The spacer layer 102 and barrier layer 104 are configured as a heterostructure that supports formation of a two-dimensional electron gas (2DEG) 105 proximate a heterojunction between the spacer layer and the barrier layer. Electric current can flow between a drain and source element via the 2DEG.

Referring to FIG. 1A, each of the cells 108 includes a plurality of source contacts 110 arrayed along a width direction Y of the cell between a first gate structure 112 and second gate structure 114. The source in the device 100 is the region of semiconductor material between the gate contacts 112, 114. In this example, the gate structures 112, 114 include corresponding doped semiconductor layers 113A, 115A, respectively, and metallic layers 113B, 115B, respectively. By way of example, the doped semiconductor layers may layers of p-type doped gallium nitride (GaN) or gallium arseninde (GaAs) and the metallic layers may be any suitable metal, such as aluminum. P-type doping of GaN may be done with magnesium (Mg). Alternative metals for the metallic layers 113B, 115B include, but are not limited to combinations of nickel (Ni) and gold (Au), combinations of nickel with platinum (Pt) and gold, combinations of titanium (Ti) and aluminum (Al), and combinations of molybdenum (Mo) with tungsten (W). Nickel may be used, e.g., to form a Ni/p-GaN Schottky contact to control leakage current. Gold is often used as a capping layer to prevent oxidation of nickel. Platinum can provide improved thermal and chemical stability.

In the case of a uni-directional HEMT device, as shown in FIG. 1A and FIG. 1B, a drain contact 116 is located between the first gate structure 112 and second gate structure 114 in each cell. The source and drain contacts are connected to corresponding metal layers in the device 100 (not shown). Each of the source contacts 110 and drain contacts 116 includes a portion that penetrates into the barrier layer to a sufficient depth to make electrical contact with the 2DEG. When a voltage is applied to the gate structures 112, 114, electric current can flow between the source contacts 110 and drain contacts 116 via the 2DEG 105. Because of the configuration of the cells 108, current can only flow in one direction between the source contacts 110 and the drain contacts 116 in the uni-directional HEMT device 100, i.e., current generally only flows under conditions of forward bias.

Certain characteristics of the device 100 depend on the dimensions of the source contacts 110, the gate contacts 112, 114, the drain contacts 116 and various distances between these contacts, such as source length SL, gate-source spacing G-S, gate length GL, gate-drain spacing G-D and drain length DL. For example the gate-drain spacing G-D controls how much voltage the device 100 can block when a reverse bias voltage is applied between the source contacts and drain contacts. For the striped cell layout depicted in in FIG. 1B, the source, gate, and drain contacts in each cell 108 straight. The dimensions of the structures that make up the cells 108 affect the cell pitch, which determines how many cells can fit in a device of a given size. Decreasing cell pitch increases the power density, which scales inversely with cell pitch. Consequently, decreasing cell pitch for a device of a given chip size device can allow the device to handle more power. Alternatively, a decreased cell pitch can allow a smaller device to handle a given amount of power.

For a device of the type of striped cell layout shown in FIG. 1A and FIG. 1B, the cell pitch Pₛₜᵣᵢₚₑ is given by Eq. 1:

$${P}_{s t r i p e} = 1 / 2 * SL + 1 / 2 * DL + G L + G - S + G - D . \qquad Eq . 1$$

The striped configuration of the cells depicted in FIG. 1A and FIG. 1B facilitates substantially constant values for the aforementioned dimensions that determine cell pitch. Unfortunately, such a striped configuration limits the degree to which pitch can be reduced. For example, source contact length is determined by how the source contact connects to the metal layer above it. Depending on voltage rating, and hence G-D space, source length can be a significant part of pitch and limit the possibility of reducing cell pitch for a striped cell layout.

It is noted that aspects of the present disclosure are not limited to implementations in which the source contacts, gate structures, and drain contacts are made of straight line segments. In alternative implementations, these structures could be curved instead of straight.

### Improved Cell Layout to Reduce Cell Pitch

According to aspects of the present disclosure an improved HEMT device may be created through the use of a cell layout in which the source contacts are islands rather than continuous stripes. The gates curve around the source contact islands and the drain contacts curves to follow the curvature and slope of the gate contacts to keep a substantially constant spacing between gate and drain along the length direction X. The locations of the island source contacts are staggered in the width direction Y to reduce the cell pitch while maintaining the substantially constant gate-drain spacing. As used herein a “substantially constant” spacing refers to spacing between two structures that is constant to within manufacturing tolerances of the process or processes used to fabricate the structures.

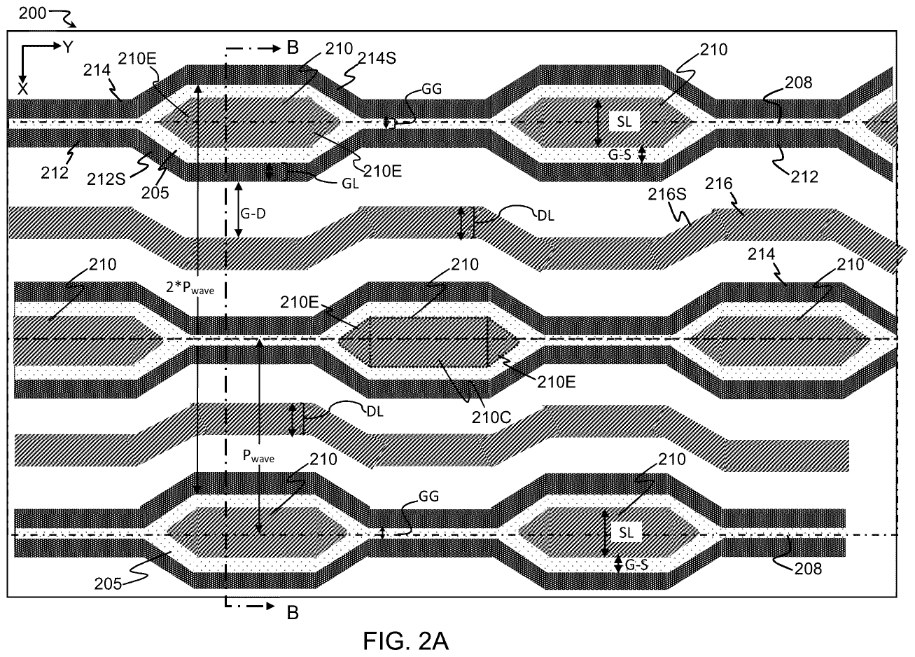

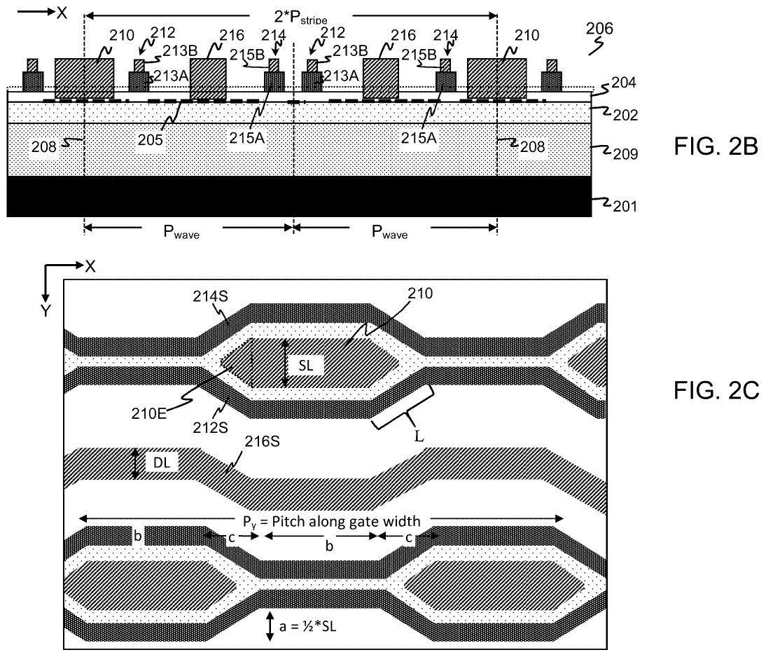

FIG. 2A and FIG. 2B illustrate an example of a uni-directional HEMT device according to aspects of the present disclosure. As seen in FIG. 2B, this type of device generally includes a semiconductor substrate 201 made of a first semiconductor material, a spacer layer 202 made of a second material, and a barrier layer 204 made of a third semiconductor material. The spacer layer is located between the substrate and barrier layer. The barrier layer is located between the spacer layer and a high electron mobility transistor (HEMT) structure 206, made up of a plurality of cells 208 that extend along a length direction X. In some implementations, an optional buffer layer 209 made of a fourth semiconductor material may be located between the substrate and the spacer layer. The spacer layer 202 and barrier layer 204 are configured as a heterostructure that supports formation of a two-dimensional electron gas (2DEG) 205 proximate a heterojunction between the spacer layer and the barrier layer. Electric current can flow between a drain and source element via the 2DEG. A source portion of the 2DEG 205 is indicated by dotted shading between the gate structures 212, 214 in FIG. 2A.

In some implementations, the second material that forms the spacer layer 202 may be a doped semiconductor material or an un-doped semiconductor material that is non-semiconducting, such as insulating gallium-nitride (i-GaN).

The optional buffer layer 209 may be present in some implementations for thermal-mechanical or electrical purposes. For example, the buffer layer may act to buffer stress during thermal cycling where the spacer layer 202 is made of GaN (either doped or un-doped) and the substrate 201 is not, e.g., where the substrate is made of silicon (Si). GaN and Si have thermal expansion coefficients and differential expansion of the substrate and spacer layer may occur, e.g., during cool down after epitaxial growth of the spacer layer or during operation of the HEMT device. The differential thermal expansion can lead to stress between the substrate 201 and spacer layer 202. The buffer layer 209 may be engineered with a coefficient of thermal expansion intermediate that of the substate and spacer layer to buffer the thermal stress. Alternatively, the buffer layer may have a coefficient of thermal expansion that gradually varies with increasing depth from a value near that of spacer layer to a value near that of the substrate.

Furthermore, the buffer layer 209 may be configured to reduce leakage current between the drain contacts and the substrate 201 during high voltage operation. Typically, the substrate 201 is held at source potential. The buffer layer 209, or portions thereof, may be doped to provide a junction diode effect that reduces leakage current to the substrate 201.

In general, to form a suitable heterojunction, the second and third semiconductor materials are to some extent different materials from each other. One or both of these materials may include combinations of materials, such as semiconductor materials made of a combination of materials from groups III and V of the periodic table, sometimes referred to as III-V semiconductors. Examples of III-V semiconductor combinations of third/second material materials for suitable heterostructures include, but are not limited to AlGaN/GaN, AlGaN/InGaN, AlGaAs/GaAs, InGaAs/GaAs. Other possible combinations include a material from group IV of the periodic table, such as silicon (Si) for the third semiconductor and a combination of two or more materials from group IV of the periodic table for the second material. Examples of such combinations include Si/SiGe. Other possible combinations of materials include semiconductors formed from elements of groups II and VI of the periodic table, sometimes referred to as II-VI semiconductors, e.g., ZnMgO—ZnO.

The source in the device 200 is the region of semiconductor material between the gate contacts 212, 214. In this example, the gate structures 212, 214 include corresponding doped semiconductor layers 213A, 215A, respectively, and metallic layers 213B, 215B, respectively. The semiconductor layers 213A, 215A are sandwiched between the barrier layer 204 and the metallic layers 213B, 215B. By way of example, the doped semiconductor layers of p-type doped gallium nitride (GaN) and the metallic layers may be any suitable metal, such as aluminum. For such a configuration of the gate structures 212, 214, the “gate length” GL measured along the X direction is the length of the semiconductor layers 213A, 215A.

In the case of a uni-directional HEMT device, as shown in FIG. 2A and FIG. 2B, a drain contact 216 is located between the first gate structure 212 and second gate structure 214 in each cell. In FIG. 2A, the metallic layers 213A, 215A are not shown for the sake of simplicity. The source contacts 210 and drain contacts 216 are connected to corresponding metal layers in the device 200 (not shown), with the source and contacts located between their respective metal layers and the barrier layer 204. Each of the source contacts 210 and drain contacts 216 includes a portion that penetrates into the barrier layer to a sufficient depth to make electrical contact with the 2DEG. When a voltage is applied to the gate structures 212, 214, electric current can flow between the source contacts 210 and drain contacts 216 via the 2DEG 205. Because of the configuration of the cells 208, current can only flow in one direction between the source contacts 210 and the drain contacts 216 in the uni-directional HEMT device 200, i.e., current generally only flows under conditions of forward bias.

Referring to FIG. 2A, each of the cells 208 includes a plurality of island source contacts 210 arrayed along a width direction Y of the cell between a first gate structure 212 and second gate structure 214. The island source contacts 210 within a given cell 208 are separated from each other along the width direction Y and staggered with respect to each other along the length direction X. The gate structures 212, 214 bend around islands to keep G-S space substantially constant and the drain contact 216 is a wavy stripe to keep the gate-drain spacing G-D substantially constant. In the illustrated example, each source contact 210 has a more or less rectangular center section 210C located between tapered end portions 210E. The sides of center portion are more or less parallel to the length direction X. In the example depicted in FIG. 2A, the gate structures 212, 214 include slanted portions 212S, 214S proximate the tapered end sections 210E of the island source contacts. The slanted portions provide a bend to the gate structures to keep a substantially fixed gate-source spacing G-S between the slanted portions 212S, 214S the tapered end portions 210E. The drain contacts similarly include slanted portions 216S that provide a bend to the drain contacts to keep a fixed gate-drain spacing G-D between the slanted portions of the drain contacts and slanted portions of the gate structures.

Although island source contacts 210 and drain contacts 216 with tapered end portions and gate structures 212, 214 with corresponding slanted portions are depicted in FIG. 2A, aspects of the present disclosure are not so limited. Alternatively, the island source and drain contacts may include tapered, beveled, chamfered, or curved end portions and the gate structures include slanted or curved portions proximate the tapered end portions that bend to maintain a substantially fixed gate-source spacing G-S and a fixed gate-drain spacing G-D. Any curved shape may be used, e.g., circular or elliptical.

Referring again to FIG. 2A, each island source contact 210 is characterized by a source contact length SL along the length direction X. Furthermore, each drain contact 216 is characterized by a drain contact length DL along the length direction X. It is desirable to design the island source contacts 210 so that the source width is as low as possible while maintaining good source contact. To maintain good source contact, it is desirable that the source contact resistance be low compared to specific On resistance (Rsp), e.g., 3 mOhm*cm or <2% of Rsp.

The gate structures 212, 214 are separated from the island source contacts 210 along the length direction X by a gate-source spacing G-S. Similarly, the gate structures 212, 214 are separated from the drain contacts 216 along the length direction X by a gate-drain spacing G-D. In the gaps between adjacent island source contacts portions of the gate structures 212, 214 are separated from each other by a gate spacing GG.

It can be seen that because the source contacts 210 are configured as island and contacts in neighboring cells are staggered the cell pitch can be reduced in the length direction X. Furthermore, by appropriately curving or bending the shape of the gate structures 212, 214 and the drain contacts 216 around the source contacts, the spacing and the cross-section of the HEMT device 200 is preserved along width direction Y. Specifically, the gate length GL, drain contact length DL, gate-source spacing G-S and gate-drain spacing G-D can be kept substantially constant.

The reduction in cell pitch may be further understood by comparing FIG. 1A to FIG. 2C, which shows a portion of the layout depicted in FIG. 2A. As noted above, in a standard stripe HEMT layout, such as that shown in FIG. 1A, the source contacts 110, gate structures 114 and drain contacts 116 are straight. The pitch Pₛₜᵣᵢₚₑ for the cells in such a layout is given by Eq. 2:

$${P}_{s t r i p e} = 1 / 2 * SL + 1 / 2 * DL + G L + G - S + G - D \qquad Eq . 2$$

For an HEMT layout of the type shown in FIG. 2A, sometimes referred to herein as a “wave layout”, the source contacts 210 are islands not stripes. The gate structures 214 bend around islands to keep G-S space substantially constant and the drain contact 216 is a wavy stripe to keep G-D space substantially constant. As may be seen from FIG. 2A, twice the pitch 2P_{wave} may be given by Eq. 3:

$$2 {P}_{w a v e} = 2 * G - S + G G + SL + 2 * DL + 4 * GL + 4 * G - D \qquad Eq . 3$$

The Half Pitch ½P_{wave} is given by:

$$1 / 2 {P}_{w a v e} = 1 / 2 * G - S + 1 / 4 * GG + 1 / 4 * SL + 1 / 2 * DL + G L + G - D \qquad Eq . 4$$

Comparing Eq. 4 to Eq. 1 above, the wave structure half pitch P_{wave} can be expressed in terms of the striped structure half pitch Pₛₜᵣᵢₚₑ, the source length SL, the gate-source spacing G-S and the gate spacing GG as shown in Eq. 5 below:

$$1 / 2 {P}_{w a v e} = {P}_{stripe} - 1 / 4 * SL - 1 / 2 * G - S + 1 / 4 * GG \qquad Eq . 5$$

The gate spacing GG and gate source spacing G-S can be made as low as possible within tolerances for the etch process that forms the gate structures 212, 214. For example, for p-type Gallium Nitride (p-GaN) etch, the tolerance is <0.5 μm in a 0.3 μm process, unconstrained by device performance. Neglecting these relatively small numbers on can approximate the wave structure half pitch ½P_{wave} as shown in Eq. 6 below:

$$1 / 2 {P}_{wave} \sim {P}_{stripe} - 1 / 4 * SL \qquad Eq . 6$$

As a numerical example, for a 650V device with ~23 μm pitch, 15.75 μm gate-drain spacing GD and 4 μm source contact length SL, using a wave layout the half pitch ½P_{wave} may be reduced by 1 μm compared to a striped layout, approximately, a 4% shrink.

In a similar 150V device with 3.75 μm gate-drain spacing G-D and 11 μm pitch Pₛₜᵣᵢₚₑ, the pitch P_{wave} of a corresponding wave layout may be reduced by 1 μm, approximately a 9% shrink. These results are summarized in Table I below.

TABLE I

| Device | Stripe | Source | WaveGaN ½ | |
|---|---|---|---|---|
| voltage | Pitch | contact | pitch | Shrink % |
| 650 V | 23 μm | 4 μm | 22 μm | 4.3% |
| 150 V | 11 μm | 4 μm | 10 μm | 9% |

### Marginal Increase in Channel Density for Uni-Directional HEMT Wave Layout

An additional benefit of a “wave” layout of the type shown in FIG. 2A is an increase in channel density as a result of the tapered portions of the source contact 210E and corresponding nearby slanted portions of the gate structures 212S, 214S. This configuration leads to an increase in channel length due to the tapered portions of the source contact 210E and slanted portions of the gate structures 212S, 214S and drain 216S.

Referring to FIG. 2C, the length direction X component of the tapered section of the gate is indicated by a. This is just half the source contact length. In the direction along width direction Y the source contact width is indicated by b, the width direction component of the source contact taper is indicated by c and the pitch along the width direction Y is indicated by Py=2(b+c), which would correspond to the channel length for a striped layout HEMT structure such as that shown in FIG. 1A. The channel length for the structure shown in FIG. 2C corresponds to the gate width GW, which is twice the source contact length b plus twice the length L of the slanted portions of the gate structures, where L=sqrt(a²+c²), as shown in Eq. 7 below.

$$GW = 2 * b + 2 * sqrt ( {c}^{2} + {a}^{2} ) \qquad Eq . 7$$

As a numerical example, assume that, half the source contact length a=2 μm the source contact width b=4 μm, and the source contact taper c=2 μm. Therefore, the pitch along the width direction Py=2 (2 μm+6 μm)=12 μm and the gate width for a wave HEMT structure like that shown in FIG. 2C would be GW=2*b+2*sqrt(c²+a²)=8+4*sqrt(2)~13.6 μm. Thus, the gate width increased by ~13% compared to a striped uni-directional HEMT structure.

The increase in channel length results in a corresponding decrease in the channel component of the specific On resistance Rsp_{channel} In the aforementioned example, the channel component of Rsp reduces by ~13%. This reduction in Rsp_{channel} is in addition to the Rsp reduction attributable to the reduction in cell pitch. The relative contributions of channel length and cell pitch to overall Rsp depend partly on the blocking voltage for which the device is design. By way of example, for a 650V uni-directional HEMT device, Rsp_{channel} is approximately 20% of overall Rsp. Consequently, a 13% reduction in Rsp_{channel} would reduce overall Rsp by about 2.6%. For a 150V device, Rsp_{channel} is about 80% of overall Rsp, so a 13% reduction in Rsp_{channel} would reduce overall Rsp by about 10.4%.

### Bidirectional GaN HEMT Cross-Section and Layout

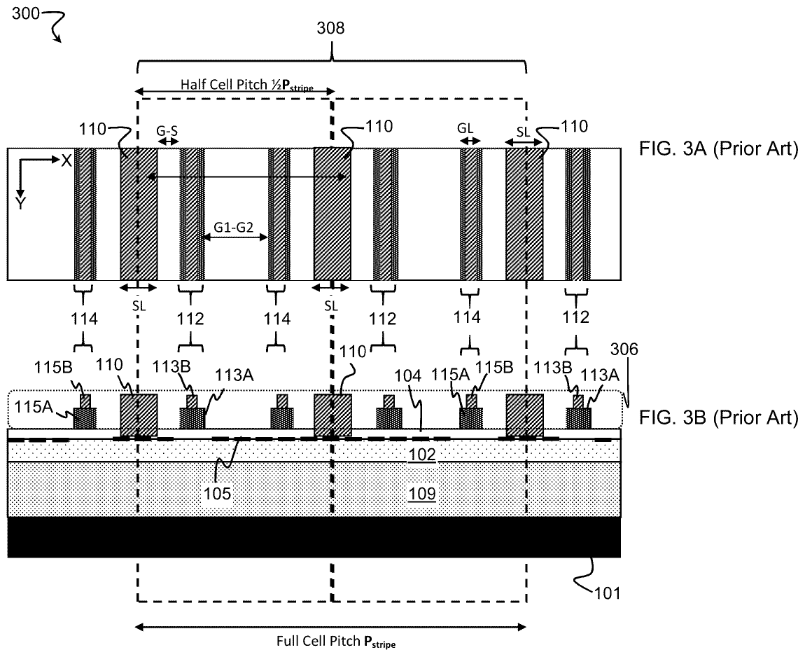

Although the device shown in FIG. 2A, FIG. 2B, and FIG. 2C is a unidirectional device, aspects of the present disclosure are not so limited. FIG. 3A shows an example of a prior art bi-directional HEMT device 300. As in the device shown in FIG. 1A and FIG. 1B source contacts 110 of source length SL and gate structures 112, 114 of gate length GL are arranged in a striped pattern with the gate structures within a cell 308 spaced apart from the source contacts by a gate spacing G-S. However, there are no drain contacts. Instead, the first gate structure 112 and second gate structure 114 in each cell are spaced apart from each other by a gate-gate spacing G1-G2.

Turning to FIG. 3B, the structure of the HEMT device 300 includes a HEMT 306 that is very similar to that of the device 100 of FIGS. 1A-1B. Specifically, the gate structures 112, 114 include similarly configured semiconductor layers 113A, 115A and metal layers 113B, 115B with the semiconductor layers sandwiched between the metal layers and a barrier layer 104. The barrier layer is, in turn, sandwiched between the HEMT structure 306 and a spacer layer 102. The spacer layer is sandwiched between the barrier layer 104 and a substrate 101. An optional buffer layer 109 may be sandwiched between the substrate and spacer layer. The substrate 101, spacer layer 102, barrier layer 104 and optional buffer layer 109 are all made of semiconductor materials and may be configured as described above with respect to FIG. 1B.

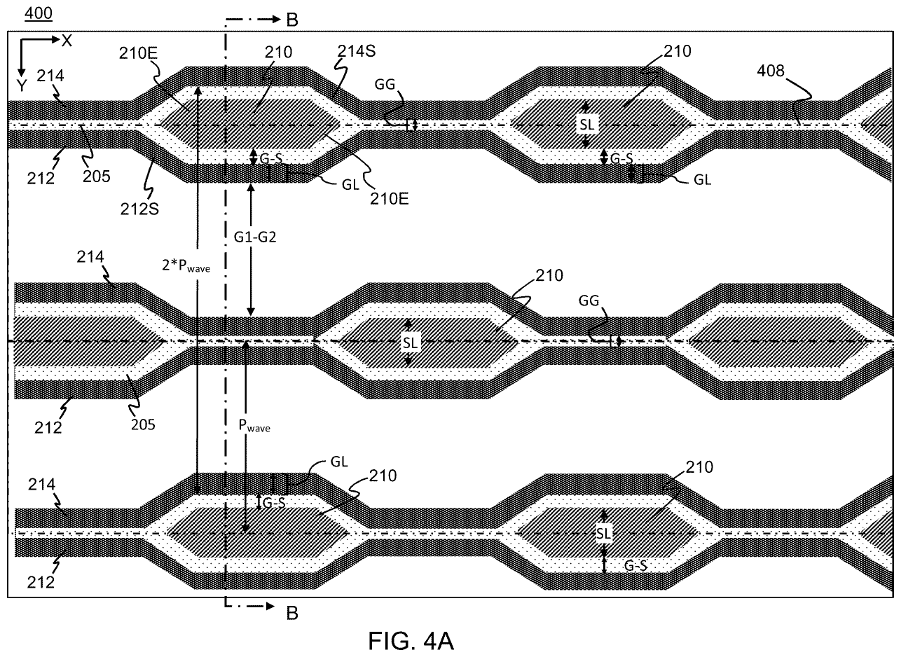

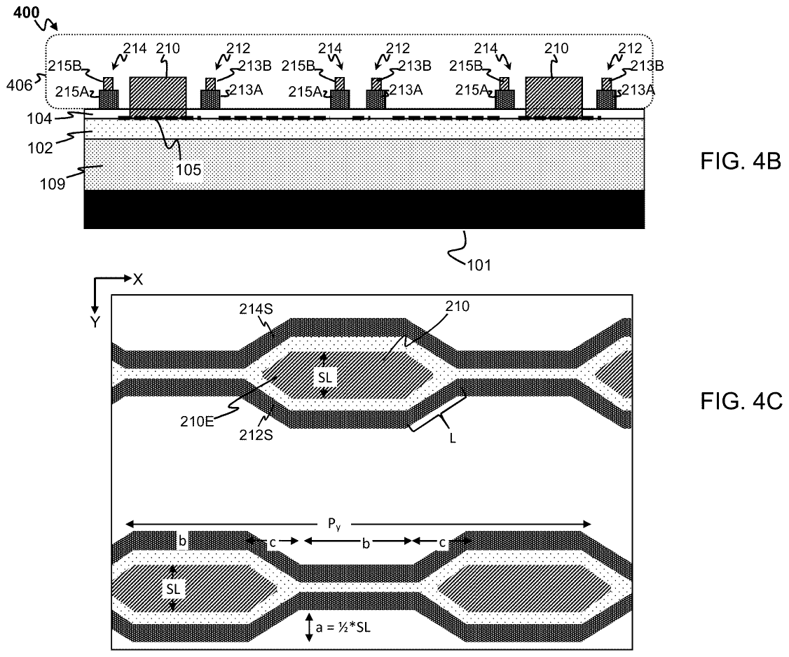

FIG. 4A and FIG. 4B illustrate an example of a bi-directional HEMT device 400 according to aspects of the present disclosure. As in the device 200 shown in FIG. 2A and FIG. 2B source contacts 210 of source length SL and gate structures 212, 214 of gate length GL are arranged in a striped pattern with the gate structures within a cell 408 spaced apart from the source contacts by a gate spacing G-S. However, there are no drain contacts. Instead, the first gate structure 212 and second gate structure 214 in each cell are spaced apart from each other by a gate-gate spacing G1-G2. Unlike the layout of the HEMT structure in the device 300 shown in FIG. 3A, the bi-directional HEMT device 400 of FIG. 4A has island source contacts 210 and gate structures 212, 214 configured in a wave-type layout similar to that shown in FIG. 2A. In particular, the island source contacts include tapered end sections 210E. Furthermore, source contacts in adjacent cells are staggered with respect to each other along the width direction Y and the gate structures 212, 214 include slanted portions 212S, 214S proximate the tapered end sections 210E of the island source contacts that bend the gate structures to keep a fixed gate-source spacing G-S between the slanted portions the tapered end portions.

Although island source contacts 210 with tapered end portions and gate structures 212, 214 with corresponding slanted portions are depicted in FIG. 4A, aspects of the present disclosure are not so limited. Alternatively, the island source contacts may include tapered, beveled, chamfered, or curved end portions and the gate structures include slanted or curved portions proximate the tapered end portions that bend to maintain a substantially fixed gate-source spacing G-S. Any curved shape may be used, e.g., circular or elliptical.

Turning to FIG. 4B, the structure of the HEMT device 400 includes a HEMT structure 406 that is very similar to that of the device 200 of FIGS. 2A-2B. Specifically, the gate structures 212, 214 include similarly configured semiconductor layers 213A, 215A and metal layers 213B, 215B with the semiconductor layers sandwiched between the metal layers and a barrier layer 204. The barrier layer is, in turn, sandwiched between the HEMT structure 406 and a spacer layer 202. The spacer layer is sandwiched between the barrier layer 204 and a substrate 201. An optional buffer layer 209 may be sandwiched between the substrate and spacer layer. The substrate 201, spacer layer 202, barrier layer 204 and optional buffer layer 209 are all made of semiconductor materials and may be configured as described above with respect to FIG. 1B.

Source contact is made an island and contacts in neighboring source lines are staggered. Gate contacts within a given cell are spaced apart by a G1-G2. Gate contacts in space between source islands are separated by a smaller gate spacing GG.

The HEMT structure 406 is configured so that its cross-section along the length direction X is preserved at every location along the width direction Y.

The reduction in cell pitch may be further understood by comparing FIG. 3A to FIG. 4A. As noted above, in a standard stripe HEMT layout, such as that shown in FIG. 3A, the source contacts 110 and gate structures 112, 114 are straight. The cell pitch P for the device 300 may be expressed as set forth in Eq. 8 below.

$${p}_{s t r i p e} = SL + 2 * GL + 2 * G - S + G 1 - G 2 \qquad Eq . 8$$

As with the uni-directional HEMT of FIGS. 2A-2C, for a bi-directional HEMT having a wave-type layout of the type shown in FIG. 4A, the source contacts 210 are islands not stripes. The gate structures 214 bend around islands to keep G-S space substantially constant. As may be seen from FIG. 4A, twice the pitch 2P_{wave} may be given by Eq. 9:

$$2 {P}_{w a v e} = 2 * G - S + G G + SL + 4 * GL + 2 * G 1 - G 2 \qquad Eq . 9$$

The Pitch P_{wave} is given by Eq. 11:

$${P}_{w a v e} = G - S + 1 / 2 * GG + 1 / 2 * SL + 2 * GL + G 1 - G 2 \qquad Eq . 10$$

Comparing Eq. 10 to Eq. 8 above, the half pitch P_{wave} for a bi-directional HEMT wave structure can be expressed in terms of the half pitch Pₛₜᵣᵢₚₑ, of a bi-directional HEMT wave structure, the source length SL, the gate-source spacing G-S and the gate spacing G1-G2 as shown in E. 11 below:

$${P}_{wave} = {P}_{stripe} - 1 / 2 * SL - G - S + 1 / 2 * G 1 - G 2 \qquad Eq . 11$$

The gate spacing G1-G2 and gate source spacing G-S can be made as low as possible within tolerances for the etch process that forms the gate structures 212, 214. As noted above, for p-GaN etch, the tolerance is <0.5 μm in a 0.3 μm process, unconstrained by device performance. Neglecting these relatively small numbers on can approximate the wave structure pitch ½P_{wave} as shown in Eq. 12 below:

$${P}_{w a v e} ∼ {P}_{s t ripe} - 1 / 2 * SL \qquad Eq . 12$$

As a numerical example, for a 650V device with ~25.5 μm pitch, 15.75 μm inter-gate spacing G1-G2 and 4 μm source contact length SL, using a wave layout the half pitch ½P_{wave} may be reduced by 1 μm compared to a striped layout, approximately, a 4% shrink.

In a similar 150V device with 3.75 μm inter-gate spacing G1-G2 and 13.5 μm half pitch ½Pₛₜᵣᵢₚₑ, the half pitch ½P_{wave} of a corresponding wave layout may be reduced by 1 μm, approximately a 7% shrink. These results are summarized in Table II below.

TABLE II

| Device | | Source | WaveGaN ½ | |
|---|---|---|---|---|
| voltage | ½ Pitch | contact | pitch | Shrink % |
| 650 V | 25.5 μm | 4 μm | 24.5 μm | 4% |
| 150 V | 13.5 μm | 4 μm | 12.5 μm | 7% |

### Marginal Increase in Channel Density for Bi-Directional HEMT Wave Layout

As with a uni-directional HEMT structure having a wave layout, an additional benefit of a wave layout for a bi-directional HEMT structure 406 of the type shown in FIG. 4A is an increase in channel density as a result of the tapered portions of the source contact 210E and corresponding nearby slanted portions of the gate structures 212S, 214S. This configuration leads to an increase in channel length due to the tapered portions of the source contact 210E and slanted portions of the gate structures 212S, 214S.

Referring to FIG. 4C, the length direction X component of the tapered section of the gate is indicated by a. This is just half the source contact length. In the direction along width direction Y the source contact width is indicated by b, the width direction component of the source contact taper is indicated by c and the pitch along the width direction Y is indicated by Py=2 (b+c), which would correspond to the channel length for a striped layout bi-directional HEMT structure such as that shown in FIG. 3A. The channel length for the structure shown in FIG. 4C corresponds to the gate width GW, which is twice the source contact length b plus twice the length L of the slanted portions of the gate structures, where L=sqrt(a²+c²), as shown in Eq. 13 below.

$$GW = 2 * b + 2 * sqrt ( {c}^{2} + {a}^{2} ) \qquad Eq . 13$$

As a numerical example, assume that, half the source contact length a=2 μm the source contact width b=4 μm, and the source contact taper c=2 μm. Therefore, the pitch along the width direction Py=2 (2 μm+6 μm)=12 μm and the gate width for a wave HEMT structure like that shown in FIG. 2C would be GW=2*b+2*sqrt(c²+a²)=8+4*sqrt(2)~13.6 μm. Thus, the gate width increased by ~13% compared to a striped HEMT structure.

The increase in channel length results in a corresponding decrease in the channel component of the specific On resistance Rsp_{channel} In the aforementioned example, the channel component of Rsp reduces by ~13%. This reduction in Rsp_{chennel} is in addition to the Rsp reduction attributable to the reduction in cell pitch. The relative contributions of channel length and cell pitch to overall Rsp depend partly on the blocking voltage for which the device is design. By way of example, for a 650V bi-directional HEMT device, Rsp_{channel} is approximately 34% of overall Rsp. Consequently, a 13% reduction in Rsp_{channel} would reduce overall Rsp by about 4%. For a 150V bi-directional HEMT device, Rsp_{channel} is about 88% of overall Rsp, so a 13% reduction in Rsp_{channel} would reduce overall Rsp by about 11%.

The reduction in cell pitch may be further understood by referring to portion of the FIG. 4C, which shows a portion of the layout depicted in FIG. 4B.

### CONCLUSION

HEMT devices that incorporate a wave layout HEMT structure can increase power density in a field effect transistor (FET), e.g., a GaN FET by reducing the specific on resistance Rsp as a result of reduced pitch and increased channel density. Combining the effects of both reduced pitch and increased channel density, an HEMT wave layout of the type described herein could improve the devices as shown in Table III below.

TABLE III

| Die shrink | HEMT | Bidi HEMT |
|---|---|---|
| 150 V | 18% | 17% |
| 650 V | 7% | 8% |

While the above is a complete description of the preferred embodiment of the present invention, it is possible to use various alternatives, modifications, and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A,” or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A semiconductor device comprising:
a semiconductor substrate made of a first semiconductor material;
a spacer layer made of a second material;
a barrier layer formed of a third semiconductor material, wherein the spacer layer is located between the semiconductor substrate and the barrier layer, and wherein the spacer layer and barrier layer are configured to support formation of a two-dimensional electron gas (2DEG) proximate a heterojunction between the spacer layer and the barrier layer;
a high electron mobility transistor (HEMT) structure formed on the spacer layer, the HEMT structure including a plurality of cells, each cell including a plurality of source contacts arrayed along a width direction of the cell between a first gate structure and second gate structure, wherein each source contact of the plurality of source contacts includes a portion that penetrates into the barrier layer to a sufficient depth to make electrical contact with the 2DEG, wherein each cell is characterized by a layout wherein the source contacts are island structures rather than continuous stripes along the width direction and wherein the gate structures divert around the island structures to keep a substantially constant gate-source (G-S) spacing between the gate structures and source contacts in a length direction perpendicular to the width direction and to keep a substantially constant gate-gate (G-G) spacing between corresponding gate structures in cells adjacent to each other along the length direction, and
wherein island structures in adjacent cells are staggered with respect to each other along the width direction.

2. The device of claim 1, wherein the island structures include tapered, beveled, chamfered, or curved end portions and the gate structures include slanted or curved portions proximate the tapered end portions.

3. The device of claim 1, wherein the HEMT structure is configured such that the device behaves as a bi-directional HEMT.

4. The device of claim 1, wherein the HEMT structure further includes a plurality of drain contacts located between adjacent cells of the plurality of cells, wherein each drain contact of the plurality of drain contacts includes a portion that penetrates into the barrier layer to a sufficient depth to make electrical contact with the 2DEG, wherein each drain contact of the plurality of drain contacts is configured to bend according to a shape of nearby gate structures to keep a substantially constant spacing between the drain contact and gate structures cells adjacent the drain contact.

5. The device of claim 4, wherein the island structures include tapered end portions and the gate structures include slanted portions proximate the tapered end portions.

6. The device of claim 5, wherein the drain contacts slanted portions proximate nearby slanted portions of the gate structures.

7. The device of claim 4, wherein the HEMT structure is configured such that the device behaves as a uni-directional HEMT.

8. The device of claim 1, wherein the first and second gate structures include a layer of p-type gallium nitride (p-GaN) located between a metal layer and the barrier layer.

9. The device of claim 1, wherein the first semiconductor material includes silicon.

10. The device of claim 9, wherein the second material is a III-V semiconductor material.

11. The device of claim 10, wherein the third semiconductor material is a III-V semiconductor material.

12. The device of claim 11, wherein the second material is insulating gallium-nitride (i-GaN) and the third semiconductor material is aluminum-gallium-nitride (AlGaN)

13. The device of claim 1, wherein the second material is a II-VI semiconductor material.

14. The device of claim 13, wherein the third semiconductor material is a II-VI semiconductor material.

15. The device of claim 1, further comprising one or more buffer layers of a fourth semiconductor material located between the semiconductor substrate and the spacer layer.

16. The device of claim 1, wherein the second, third, and fourth semiconductor materials are III-V semiconductor materials.

17. The device of claim 14, wherein the second material is insulating gallium-nitride, the third semiconductor material is aluminum-gallium-nitride, and the fourth semiconductor material is gallium nitride.
